(19) United States
(12) Patent Application Publication
(10) Pub. No.: US 2010/0118625 A1
(43) Pub. Date: May 13, 2010

(54) CHARGE PUMP CIRCUIT AND SEMICONDUCTOR MEMORY DEVICE INCLUDING THE SAME

(75) Inventor: Tatsuya Matano, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: Elpida Memory, Inc., Tokyo (JP)

(21) Appl. No.: 12/615,953

(22) Filed: Nov. 10, 2009

(30) Foreign Application Priority Data
Nov. 12, 2008 (JP) 2008-290246

(51) Int. Cl. G11C 7/00; G05F 1/10

(52) U.S. Cl. 365/189.16; 327/536

(57) ABSTRACT

A charge pump circuit includes a first charge pump unit that includes a first capacitor and a second capacitor connected in parallel and generates a first charge pump voltage in the second capacitor by pumping the first capacitor, and a second charge pump unit that includes a third capacitor connected to the second capacitor in series and generates a second charge pump voltage in the second capacitor by further pumping the first charge pump voltage charged in the second capacitor via the third capacitor. In this manner, by pumping the latter stage capacitor from among the capacitors connected in parallel by a parallel connection method, the voltage applied between the capacitor electrodes of the latter stage capacitor is lowered.

### BACKGROUND OF THE INVENTION

1. Field of the Invention

The present invention relates to a charge pump circuit and a semiconductor memory device including the same, and more particularly relates to a multistage charge pump circuit including a plurality of capacitors and a semiconductor memory device including the same.

2. Description of Related Art

Some semiconductor devices require a boost potential that is higher than a power source potential supplied from the outside or a negative potential that is lower than a ground potential. Such semiconductor devices include a built-in charge pump circuit for generating a boost potential or a negative potential (see Japanese Patent Application Laid-open Nos. 2000-3598 and 2003-33007).

The charge pump circuit is a power supply circuit that performs a boost operation based on pumping using capacitors, and can perform a large step-up by using a plurality of capacitors. A multistage charge pump circuit that uses a plurality of capacitors is roughly divided into a type in which the capacitors are connected in parallel (a parallel connection method) and a type in which the capacitors are connected in series (a series connection method).

The parallel connection method has an advantage in that the boost efficiency is high because a charge loss due to a parasitic capacitance is low. However, because the later stage capacitor has a higher voltage applied between a pair of capacitor electrodes, there is a problem that a withstanding voltage of a capacitor insulating film included in the later stage capacitor becomes insufficient. To solve this problem, it is required to increase the withstanding voltage by increasing the thickness of the capacitor insulating film included in the later stage capacitor. However, because the capacitance decreases as the thickness of the capacitor insulating film increases, areas of the capacitor electrodes need to be increased to achieve a desired capacitance, which results in another problem that the occupied area of the electrodes increases.

On the other hand, the series connection method does not have a problem of insufficient withstanding voltage of the capacitor insulating film, because all capacitors have the same level of a voltage applied between a pair of capacitor electrodes as the level of the power source voltage. However, in the series connection method, there is a problem that the boost efficiency is relatively low because the charge loss due to the parasitic capacitance is high.

As describe above, the parallel connection method and the series connection method have both merits and demerits. Therefore, a development of an improved charge pump circuit has been desired.

### SUMMARY

The present invention seeks to solve one or more of the above problems, or to improve upon those problems at least in part.

In one embodiment, there is provided a charge pump circuit comprising: a first charge pump unit that includes a first capacitor and a second capacitor connected in parallel, and generates a first charge pump voltage in the second capacitor by pumping the first capacitor; and a second charge pump unit that includes a third capacitor connected to the second capacitor in series, and generates a second charge pump voltage in the second capacitor by further pumping the first charge pump voltage charged in the second capacitor via the third capacitor.

In another embodiment, there is provided a charge pump circuit comprising: a first capacitor that includes a first capacitor electrode configured to be pre-charged and a second capacitor electrode configured to be pumped; a second capacitor that includes a third capacitor electrode and a fourth capacitor electrode, the third capacitor electrode configured to be connected to the first capacitor electrode via a first switch; and a third capacitor that includes a fifth capacitor electrode and a sixth capacitor electrode, the fifth capacitor electrode configured to be connected to the fourth capacitor electrode via a second switch, the sixth capacitor electrode configured to be pumped.

In still another embodiment, there is provided a charge pump circuit comprising: a first charge pump unit of a parallel connection method including M number of capacitors connected in parallel, where M is an integer equal to or larger than 2; and a second charge pump unit of a series connection method including N number of capacitors connected in series, where N is an integer equal to or larger than 2, wherein a capacitor that forms each last stage of the first and second charge pump units is shared.

In still another embodiment, there is provided a semiconductor memory device comprising: a word line; a bit line; a memory cell for which a current path is formed with the bit line in response to activation of the word line; a write circuit that supplies a write current to the bit line; and the above described charge pump circuit that supplies an operation voltage to the write circuit, wherein the memory cell includes a phase change element in which a phase state is changed by a write current supplied from the bit line.

According to the present invention, because the latter stage capacitor from among capacitors connected in parallel is pumped by the series connection method, the voltage applied between the capacitor electrodes of the latter stage capacitor is lowered. Therefore, the withstanding voltage of the capacitor insulating film included in the latter stage capacitor can be ensured, while realizing a boost operation with high efficiency by the parallel connection method. The charge pump circuit according to the present invention is not limited to a circuit for generating a boost potential higher than the power source potential, but can be applied to a circuit for generating a negative potential lower than a ground potential.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a circuit diagram of a charge pump circuit 100 according to a first embodiment of the present invention;

FIG. 2 is a detailed circuit diagram of the charge pump circuit 100;

FIG. 3 is an operation waveform chart of the charge pump circuit 100;

FIG. 4 is a circuit diagram of a modification example of the charge pump circuit 100 shown in FIG. 1;

FIG. 5 is a circuit diagram of a charge pump circuit 200 according to a second embodiment of the present invention;

FIG. 6 is a circuit diagram of a charge pump circuit 300 according to a third embodiment of the present invention;

FIG. 7 is a circuit diagram of a charge pump circuit 400 according to a fourth embodiment of the present invention;

FIG. 8 is a block diagram of a semiconductor memory device 500 according to a fifth embodiment of the present invention; and

FIG. 9 is a circuit diagram wherein the capacitor in each embodiment of the present invention is shown by using a MOS transistor.

### DETAILED DESCRIPTION OF THE EMBODIMENTS

Preferred embodiments of the present invention will be explained below in detail with reference to the accompanying drawings.

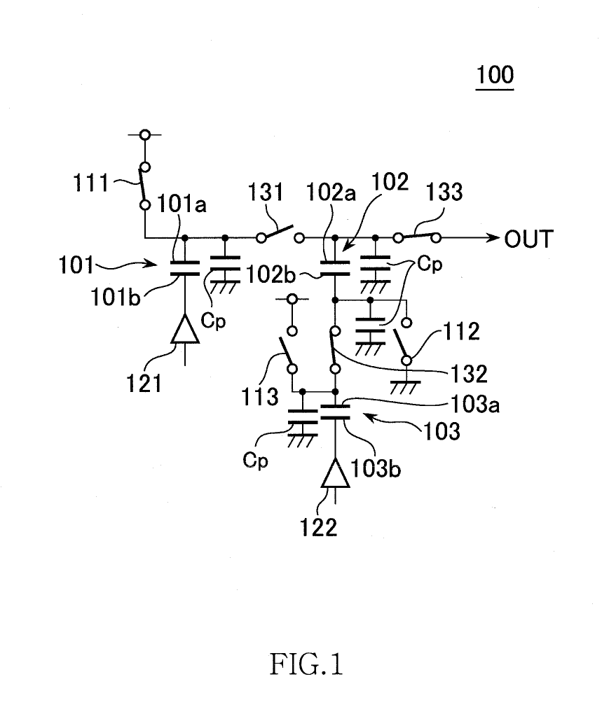

FIG. 1 is a circuit diagram of a charge pump circuit 100 according to a first embodiment of the present invention.

As shown in FIG. 1, the charge pump circuit 100 according to the first embodiment includes a first capacitor 101, a second capacitor 102, and a third capacitor 103. The first and the second capacitors 101 and 102 are connected to each other in parallel, and the third capacitor is connected to the second capacitor 102 in series. The first and second capacitors 101 and 102 form a charge pump unit of the parallel connection method, and the second capacitor 102 and the third capacitor 103 form a charge pump unit of the series connection method. That is, the present invention has a configuration such that the second capacitor 102 that constitutes the last stage of the charge pump unit of the parallel connection method is shared by the charge pump unit of the series connection method.

With the above configuration, it is possible to generate a charge pump voltage V1 in the second capacitor 102 by pumping the first capacitor 101, and to generate a charge pump voltage V2 in the second capacitor 102 by further pumping the charge pump voltage V1 accumulated in the second capacitor 102 via the third capacitor 103. The charge pump voltage V1 is a difference potential between a boost potential V1 and a ground potential VSS (V1=V1−VSS), which are described later. The charge pump voltage V2 is a difference potential between a boost potential V2 and a ground potential VSS (V2=V2−VSS), which are described later.

To be more specific, a pre-charge circuit 111 that pre-charges a capacitor electrode 101a of the first capacitor 101 by supplying a power source potential VDD is connected to the first capacitor electrode 101a, and a driver 121 is connected to another capacitor electrode 101b. When an output of the driver 121 is changed from the ground potential VSS to the power source potential VDD after pre-charging the capacitor electrode 101a to the power source potential VDD, the capacitor electrode 101a is boosted to the boost potential V1 by pumping. The level of the boost potential V1 is ideally VDD×2; however, because there is a loss due to existence of a parasitic capacitance Cp, it is practically lower than VDD×2.

As shown in FIG. 1, a switch 131 is provided between the capacitor electrode 101a of the first capacitor 101 and a capacitor electrode 102a of the second capacitor 102. Therefore, when the switch 131 is turned on when another capacitor electrode 102b of the second capacitor 102 is set to the ground potential VSS, the charge accumulated in the first capacitor 101 is transferred to the second capacitor 102. If the charge amount in the second capacitor 102 is low before transferring the charge, due to the output voltage dependency of an output OUT, after transferring the charge, a voltage Via that is lower than the charge pump voltage V1 is generated between a pair of the first and second capacitor electrodes 102a and 102b of the second capacitor 102.

A switch 132 is provided between the capacitor electrode 102b of the second capacitor 102 and a capacitor electrode 103a of the third capacitor 103. Furthermore, a driver 122 is connected to another capacitor electrode 103b of the third capacitor 103. Moreover, a pre-charge circuit 112 that pre-charges the capacitor electrode 102b of the second capacitor 102 to the ground potential VSS is connected to the capacitor electrode 102b, and a pre-charge circuit 113 that pre-charges the capacitor electrode 103a of the third capacitor 103 to the power source potential VDD is connected to the capacitor electrode 103a.

With the above configuration, after pre-charging the capacitor electrodes 102b and 103a to the ground potential VSS and the power source potential VDD, respectively, in a state where the switch 132 is turned off, if the switch 132 is turned on and an output of the driver 122 is changed from the ground potential VSS to the power source potential VDD, the capacitor electrode 103b is boosted to a boost potential V3 by pumping. The level of the boost potential V3 is ideally VDD×2. Thus, the second capacitor 102 is ideally pumped by V3, and the capacitor electrode 102a is boosted to V2.

Thereafter, if a switch 133 that is connected between the second capacitor 102 and an output terminal OUT is turned on, a current flows from the second capacitor 102 to the output terminal OUT, and a voltage V2a that is lower than the boost voltage V2 is generated between a pair of the capacitor electrodes 102a and 102b of the second capacitor 102.

Because a voltage between both terminals of the first and third capacitors 101 and 103 is VDD, respectively, and a voltage between both terminals of the second capacitor 102 is Via (VDD<V1a<2VDD), it is possible to ensure the withstanding voltage of the capacitor insulating film included in the second capacitor 102. In a case that all the three capacitors 101 to 103 are connected in parallel, the voltage between both terminals of the last stage capacitor becomes below 3VDD, and thus the withstanding voltage of the capacitor insulating film included in the last stage capacitor becomes insufficient. On the other hand, if all the three capacitors 101 to 103 are connected in series, the voltage between both terminals of each of the capacitors can be suppressed to about VDD. However, because the charge loss due to the parasitic capacitance is high, a boost potential that can be finally achieved is decreased.

In contrast, in the charge pump circuit 100 according to the first embodiment, because a combination of the charge pump unit of the parallel connection method and the charge pump unit of the series connection method is employed, the voltage between both terminals of the second capacitor 102, which is the last stage capacitor, is suppressed below 2VDD while ensuring a high boost efficiency using the three stage capacitors. Therefore, it is possible to ensure the withstanding voltage of the second capacitor 102 that is the last stage capacitor.

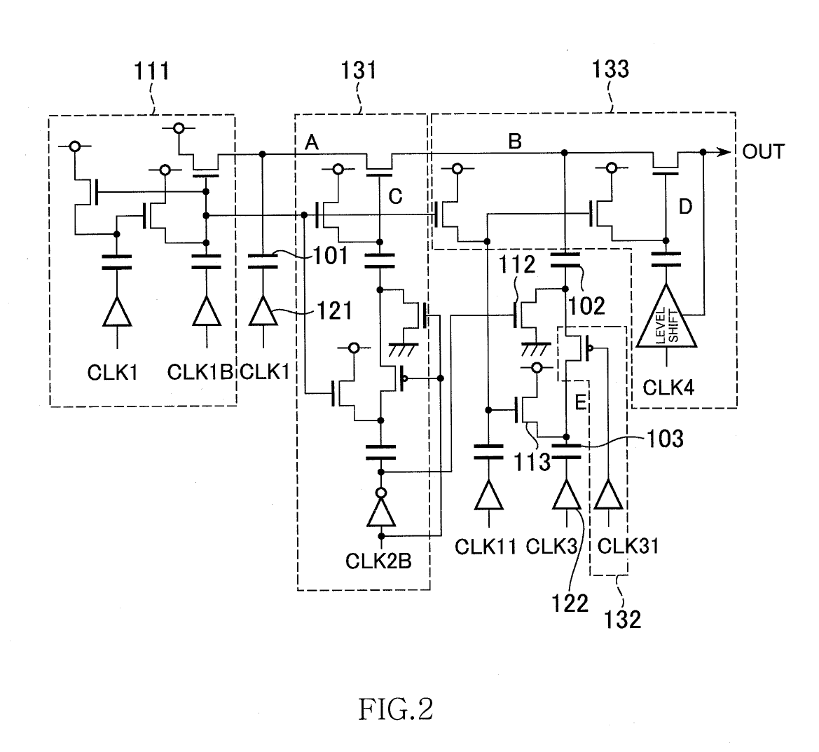

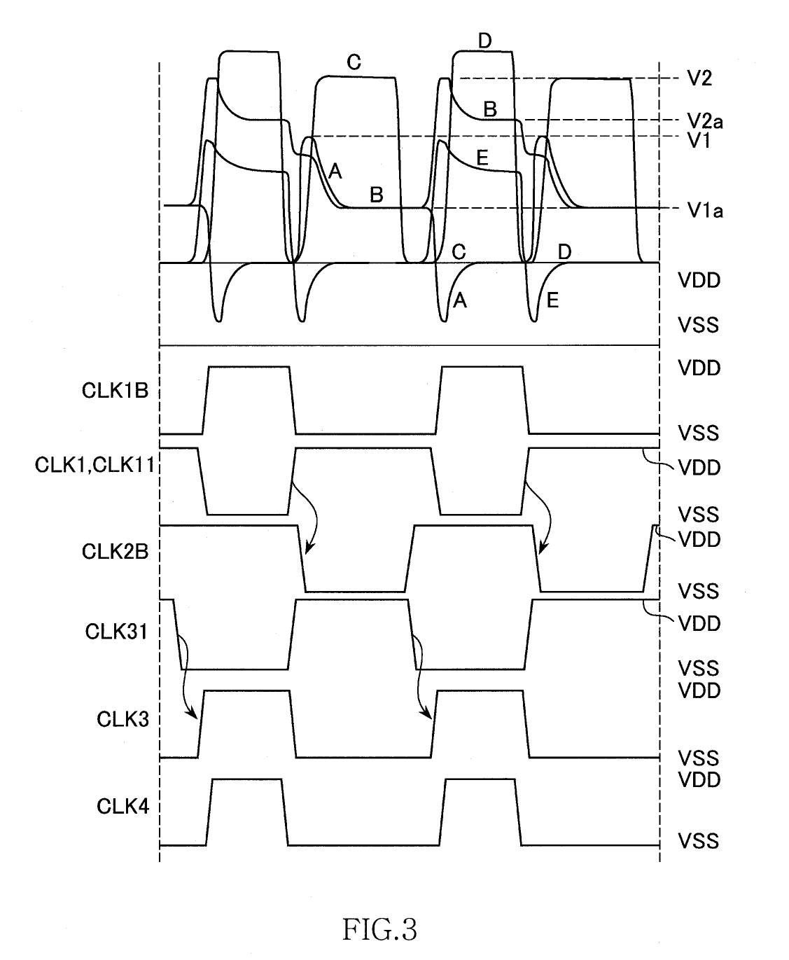

FIG. 2 is a detailed circuit diagram of the charge pump circuit 100 according to the first embodiment, and FIG. 3 is an operation waveform chart thereof.

As shown in FIG. 2, the pre-charge circuit 111 is controlled by clock signals CLK1 and CLK1B, the pre-charge circuit 112 is controlled by a clock signal CLK2B, and the pre-charge circuit 113 is controlled by a clock signal CLK11. The driver 121 is controlled by the clock signal CLK1, and the driver 122 is controlled by a clock signal CLK3. Further, the switch 131 is controlled by the clock signal CLK2B, the switch 132 is controlled by a clock signal CLK31, and the switch 133 is controlled by a clock signal CLK4. When the waveforms of the clock signals are set to the ones shown in FIG. 3, the charge pump voltage V2 is output to the output terminal Out in synchronization with a cycle in which the level of the clock signal CLK4 is High.

That is, the first capacitor 101 is pumped with the level of the clock signal CLK1 set to High, and then the charge pump voltage Via is generated in the second capacitor 102 with the level of the clock signal CLK2B set to Low and the switch 131 is turned on. Subsequently, the switch 132 is turned on with the level of the clock signal CLK31 set to Low, and then, the charge pump voltage V2 is generated in the second capacitor 102 by pumping the third capacitor 103 with the level of the clock signal CLK3 set to High. Finally, the boost voltage is supplied to the output OUT by turning on the switch 133 with the level of the clock signal CLK4 set to High.

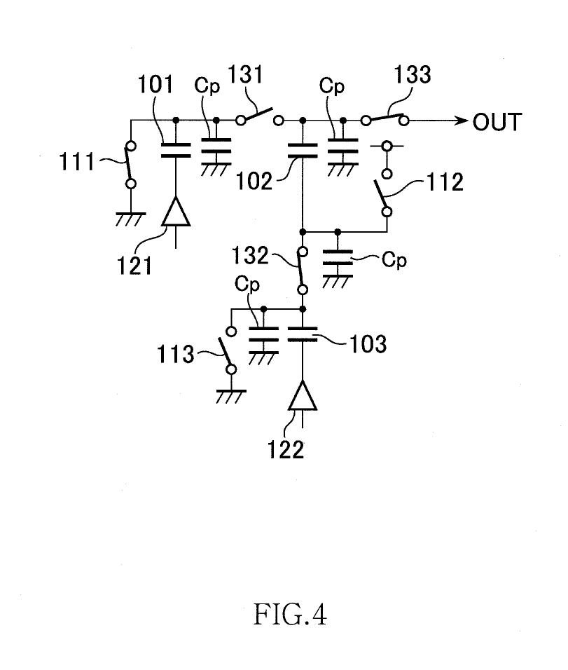

FIG. 4 is a circuit diagram of a modification example of the charge pump circuit 100 shown in FIG. 1, for generating a negative potential that is lower than the ground potential VSS. The circuit shown in FIG. 4 has a substantially same circuit configuration as the charge pump circuit 100 shown in FIG. 1, except that the pre-charge potential is different. In this manner, the charge pump circuit according to the first embodiment can not only generate a boost potential that is higher than the power source potential VDD but also generate a negative potential that is lower than the ground potential VSS.

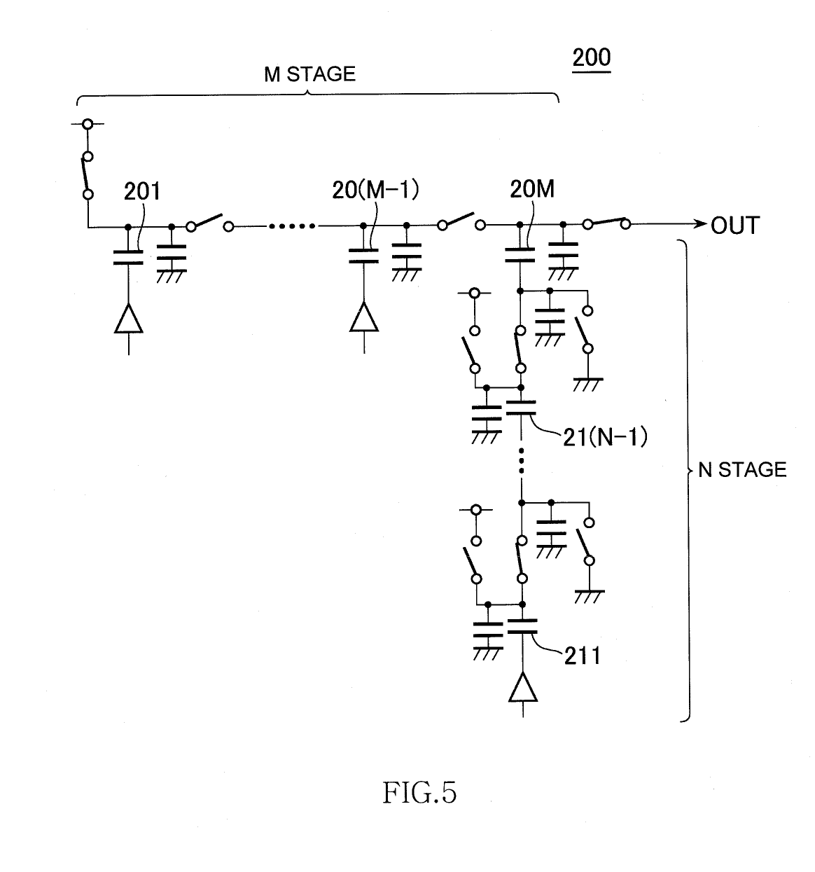

FIG. 5 is a circuit diagram of a charge pump circuit 200 according to a second embodiment of the present invention.

As shown in FIG. 5, the charge pump circuit 200 according to the second embodiment includes an M-stage charge pump unit of the parallel connection method (where M is an integer equal to or larger than 2) and an N-stage charge pump unit of the series connection method (where N is an integer equal to or larger than 2). That is, the M-stage charge pump unit includes M number of capacitors 201 to 20M connected in parallel, and the N-stage charge pump unit includes N number of capacitors 211 to 20M connected in series. The capacitor 20M that forms the last stage of the charge pump unit of the parallel connection method is shared by the charge pump unit of the series connection method. The circuit configuration of each stage is the same as that of each stage of the charge pump unit shown in FIG. 1.

With the charge pump circuit 200 according to the second embodiment, it is possible to achieve a higher boost potential (ideally, VDD×(M+N)). Furthermore, the voltage applied between both electrodes of the last stage capacitor 20M is suppressed to VDD×M. In the second embodiment, the magnitude relationship between M and N is not particularly limited.

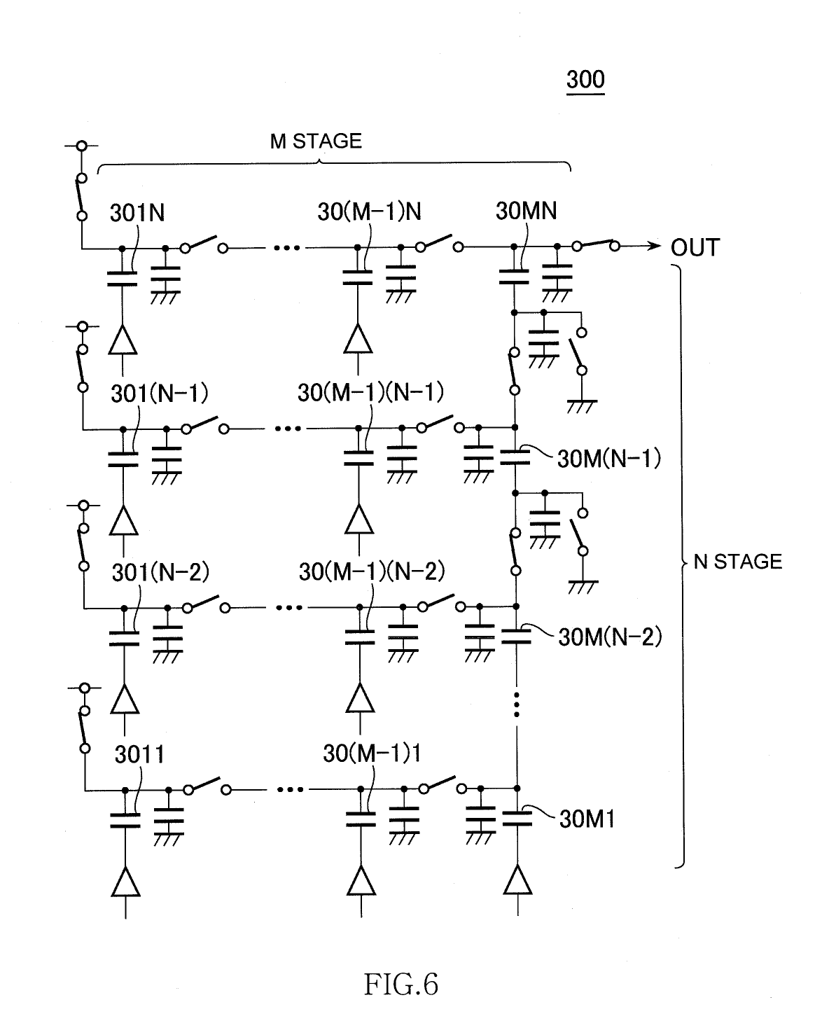

FIG. 6 is a circuit diagram of a charge pump circuit 300 according to a third embodiment of the present invention.

As shown in FIG. 6, the charge pump circuit 300 according to the third embodiment includes N number of M-stage charge pump units of the parallel connection method, with each of the last stages forming an N-stage charge pump unit of the series connection method. That is, each of the M-stage charge pump units includes M number of capacitors 301i to 30Mi (where i=1 to N), and the capacitors 30M1 to 30MN forming the last stages of the M-stage charge pump units, respectively, are connected in series. The circuit configuration of each stage is the same as that of each stage of the charge pump unit shown in FIG. 1.

With the charge pump circuit 300 according to the third embodiment, it is possible to achieve an even higher boost potential (ideally, VDD×(M×N+1); however, it becomes a lower potential because of the parasitic capacitance Cp and the output voltage dependency). Furthermore, because N number of charge pump voltages of VDD×(M+1) are generated ideally by the M-stage charge pump units of the parallel connection method and the charge pump voltages thus generated are used in pumping by the series connection method, the voltage applied to both electrodes of the last stage capacitor 30MN is suppressed to VDD×M in the same manner as the charge pump circuit 200 according to the second embodiment. Although the number of stages of the N number of charge pump units of the parallel connection method is M in the third embodiment, the number of the stages is not necessarily to be M.

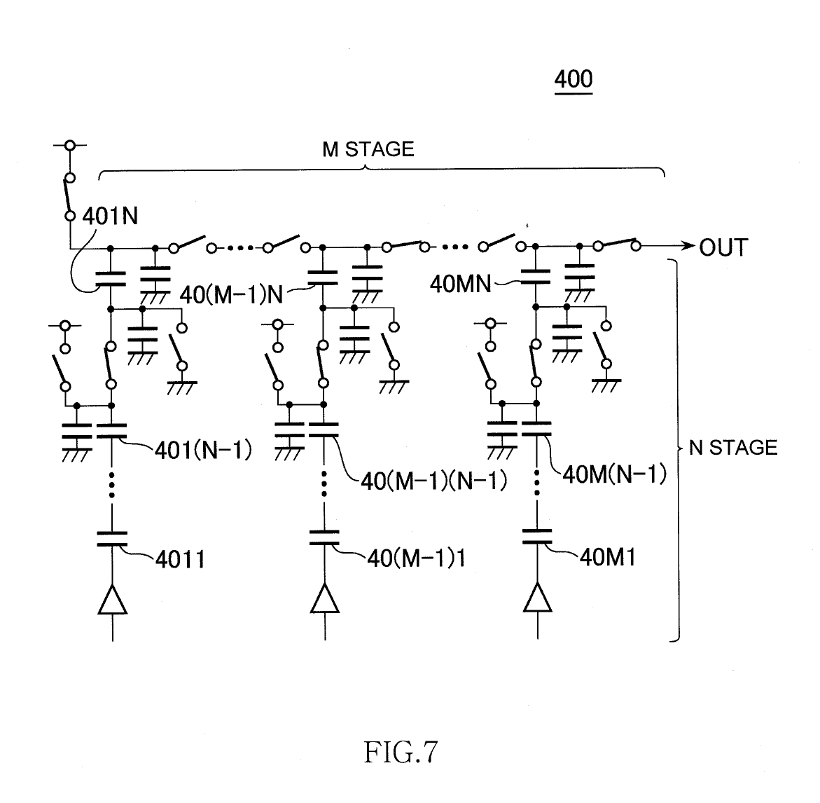

FIG. 7 is a circuit diagram of a charge pump circuit 400 according to a fourth embodiment of the present invention.

As shown in FIG. 7, the charge pump circuit 400 according to the fourth embodiment includes M number of N-stage charge pump units of the series connection method, with each of the last stages forming an M-stage charge pump unit of the parallel connection method. That is, each of the N-stage charge pump units includes N number of capacitors 40j1 to 40jN (where j=1 to M), and the capacitors 401N to 40MN forming the last stages of the N-stage charge pump units, respectively, are connected in parallel. The circuit configuration of each stage is the same as that of each stage of the charge pump unit shown in FIG. 1.

With the charge pump circuit 400 according to the fourth embodiment, it is possible achieve to a boost potential as high as that of the charge pump circuit 300 according to the third embodiment (ideally, VDD×(M×N+1); however, it becomes a lower potential because of the parasitic capacitance Cp and the output voltage dependency). Furthermore, the voltage applied between both electrodes of the last stage capacitor 40MN is suppressed to VDD×{(M−1)×N−1}. In addition, although the number of stages of the M number of charge pump units of the series connection method is N in the fourth embodiment, the number of the stages is not necessarily to be N.

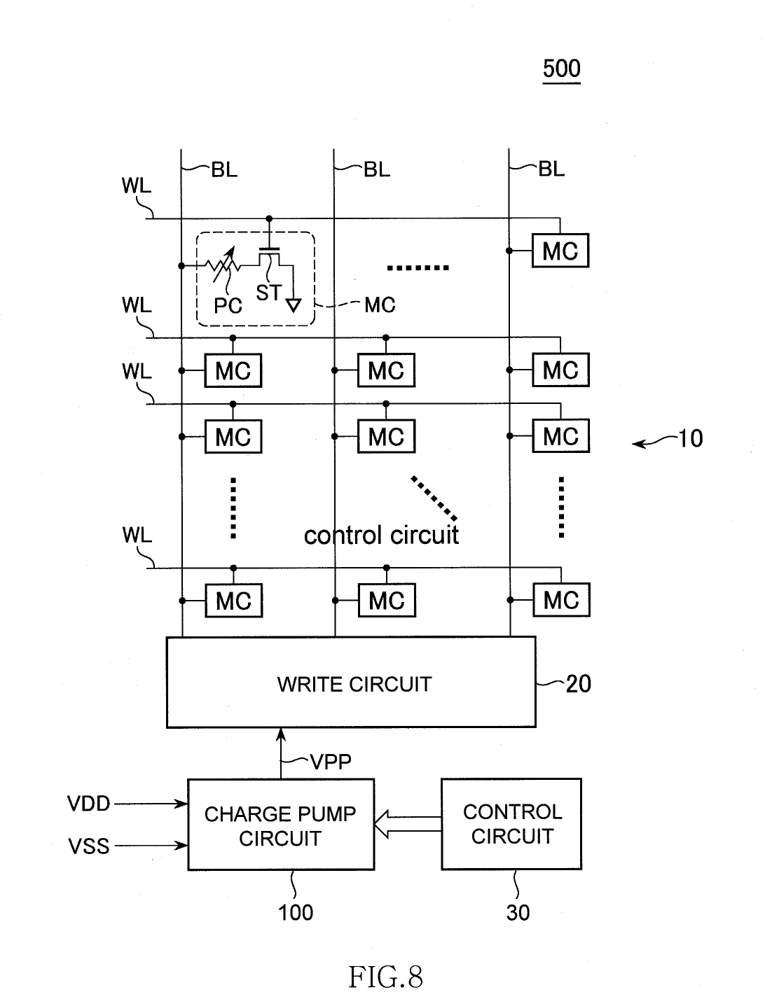

FIG. 8 is a block diagram of a semiconductor memory device 500 according to a fifth embodiment of the present invention.

As shown in FIG. 8, the semiconductor memory device 500 according to the fifth embodiment includes a memory cell array 10, a write circuit 20, a charge pump circuit 100, and a control circuit 30. The control circuit 30 supplies various clock signals (see FIGS. 2 and 3) required for an operation of the charge pump circuit 100 to the charge pump circuit 100. A circuit configuration of the charge pump circuit 100 is as stated above.

The memory cell array 10 includes a plurality of word lines WL, a plurality of bit lines BL, and a plurality of memory cells MC each arranged at a point at the intersection of each of the word lines WL with each of the bit lines BL. The memory cell MC has a configuration in which a series circuit of a phase change element PC of which the phase state is changed and a select transistor ST is connected to a corresponding one of the bit line BL, and a gate electrode of the select transistor ST is connected to a corresponding one of the word line WL. With this configuration, when a predetermined word line WL is activated, a current path is formed between a corresponding one of the bit line BL and the phase change element PC, and a write current or a read current can be supplied via the bit line BL.

The supply of the write current is performed by the write circuit 20. When the memory cell MC that is a write target is set to a high resistance state (a reset state), the write circuit 20 supplies a reset current to the bit line BL, thus heating a phase change material included in the phase change element PC to a temperature above its melting point. After the heating, the phase change element PC becomes an amorphous state by being rapidly cooled. On the other hand, when the memory cell MC that is the write target is set to a low resistance state (a set state), the write circuit 20 supplies a set current to the bit line BL, thus heating the phase change material included in the phase change element PC to a temperature above its crystallizing point and below its melting point. Thereafter, the phase change element PC becomes a crystalline state by being slowly cooled.

To change the phase state of the phase change element PC by applying the reset current and the set current, it is necessary to boost the voltage of the bit line BL to a relatively high voltage. Therefore, the write circuit 20 receives a boost potential VPP from the charge pump circuit 100, and generates the reset current and the set current using the boost potential VPP. In this manner, by employing the charge pump circuit 100 described above in the semiconductor memory device 500 that uses the phase change element PC, it is possible to generate the boost power source VPP with a small occupied area and a high efficiency. Of course, if a higher boost potential VPP is required, the charge pump circuit 200, the charge pump circuit 300, or the charge pump circuit 400 can be used instead of the charge pump circuit 100.

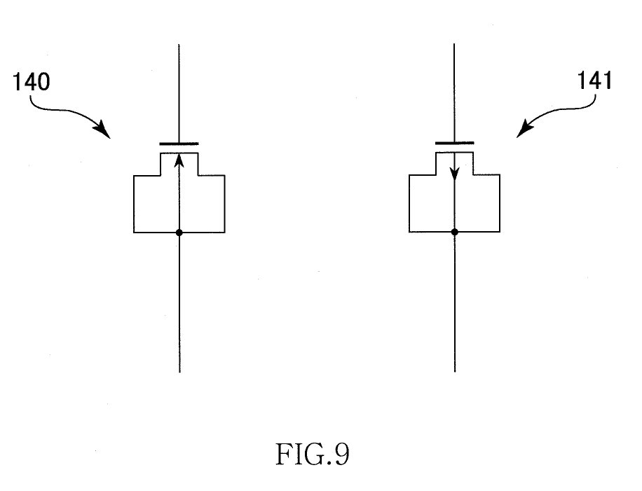

The capacitors in the above embodiments can be formed with a MOS transistor, as shown in FIG. 9. For example, the second capacitor 102 shown in FIG. 1 can be formed with an NMOS transistor 140. The capacitor electrode 102a of the second capacitor 102 is connected to a gate electrode, and the capacitor electrode 102b is connected to a source, a drain, and a substrate. The same goes for the other capacitors. Further, when the second capacitor 102 is formed with a PMOS transistor 141, the capacitor electrode 102a is connected to a source, a drain, and a substrate, and the capacitor electrode 102b is connected to a gate electrode. For two or more capacitors, the capacitors can be configured by combining the NMOS transistor 140 and the PMOS transistor 141.

It is apparent that the present invention is not limited to the above embodiments, but may be modified and changed without departing from the scope and spirit of the invention.

What is claimed is:

1. A charge pump circuit comprising:
a first charge pump unit that includes a first capacitor and a second capacitor connected in parallel, and generates a first charge pump voltage in the second capacitor by pumping the first capacitor; and
a second charge pump unit that includes a third capacitor connected to the second capacitor in series, and generates a second charge pump voltage in the second capacitor by further pumping the first charge pump voltage charged in the second capacitor via the third capacitor.

2. The charge pump circuit as claimed in claim 1, wherein the first charge pump unit includes three or more capacitors connected in parallel including the first capacitor and the second capacitor, and generates the first charge pump voltage in the second capacitor by sequentially pumping the three or more capacitors connected in parallel.

3. The charge pump circuit as claimed in claim 1, wherein the second charge pump unit includes a plurality of capacitors connected in series including the third capacitor, and generates the second charge pump voltage in the second capacitor by pumping the second capacitor via the capacitors connected in series.

4. The charge pump circuit as claimed in claim 1, further comprising a third charge pump unit that includes a fourth capacitor connected to the third capacitor in parallel, and generates a third charge pump voltage in the third capacitor by pumping the fourth capacitor.

5. The charge pump circuit as claimed in claim 1, further comprising a fourth charge pump unit that includes a fifth capacitor connected to the first capacitor in series, and generates the first charge pump voltage in the first capacitor by pumping the first capacitor via the fifth capacitor.

6. A charge pump circuit comprising:
a first capacitor that includes a first capacitor electrode configured to be pre-charged and a second capacitor electrode configured to be pumped;
a second capacitor that includes a third capacitor electrode and a fourth capacitor electrode, the third capacitor electrode configured to be connected to the first capacitor electrode via a first switch; and
a third capacitor that includes a fifth capacitor electrode and a sixth capacitor electrode, the fifth capacitor electrode configured to be connected to the fourth capacitor electrode via a second switch, the sixth capacitor electrode configured to be pumped.

7. The charge pump circuit as claimed in claim 6, further comprising a pre-charge circuit that pre-charges the fourth capacitor electrode and the fifth capacitor electrode to different potentials from each other in a state that the second switch is turned off.

8. The charge pump circuit as claimed in claim 6, wherein the charge pump circuit generates a first charge pump voltage in the second capacitor by turning on the first switch after pumping the second capacitor electrode, and generates a second charge pump voltage in the second capacitor by pumping the sixth capacitor electrode after turning on the second switch.

9. A charge pump circuit comprising:
a first charge pump unit of a parallel connection method including M number of capacitors connected in parallel, where M is an integer equal to or larger than 2; and
a second charge pump unit of a series connection method including N number of capacitors connected in series, where N is an integer equal to or larger than 2, wherein
a capacitor that forms each last stage of the first and second charge pump units is shared.

10. A charge pump circuit including a first capacitor, a second capacitor, and a third capacitor, wherein
a charge state of the second capacitor is changed from a first state to a second state by charging at least a portion of an electric charge of the first capacitor in the second capacitor; and
a voltage based on an electric charge of the third capacitor is added to a voltage based on an electric charge in the second state of the second capacitor.

11. A semiconductor memory device comprising:
a word line;
a bit line;
a memory cell for which a current path is formed with the bit line in response to activation of the word line;
a write circuit that supplies a write current to the bit line; and
a charge pump circuit that supplies an operation voltage to the write circuit, wherein
the charge pump circuit includes:
a first charge pump unit that includes a first capacitor and a second capacitor connected in parallel, and generates a first charge pump voltage in the second capacitor by pumping the first capacitor; and
a second charge pump unit that includes a third capacitor connected to the second capacitor in series, and generates a second charge pump voltage in the second capacitor by further pumping the first charge pump voltage charged in the second capacitor via the third capacitor,
the memory cell includes a phase change element in which a phase state is changed by a write current supplied from the bit line.

12. A voltage generation circuit comprising:
a first capacitive element operatively controlled to boost a first voltage to a second voltage;
a second capacitive element operatively controlled to boost a third voltage to a fourth voltage; and
a third capacitive element operatively controlled to be charged with the second voltage, and then supplied at a first terminal thereof with the fourth voltage thereof to produce at a second terminal thereof a fifth voltage which is larger than the second and fourth voltages.

13. The voltage generation circuit as claimed in claim 12, further comprising a first switch provided between the first capacitive element and the third capacitive element to supply the third capacitive element with the second voltage, and a second switch provided between the second capacitive element and the third capacitive element to supply the third capacitive element with the fourth voltage.

14. The voltage generation circuit as claimed in claim 12, further comprising a first voltage terminal supplied with the first voltage, a third switch provided between the first voltage terminal and the first capacitive element, a second voltage terminal supplied with the third voltage, and a fourth switch provided between the second voltage terminal and the second capacitive element.

15. The voltage generation circuit as claimed in claim 12, wherein the first voltage is substantially equal to the third voltage.
